(19) United States
(12) Patent Application Publication
(10) Pub. No.: US 2019/0088784 A1
(43) Pub. Date: Mar. 21, 2019

(54) THIN FILM TRANSISTOR, METHOD FOR MANUFACTURING THE SAME, BASE SUBSTRATE AND DISPLAY DEVICE

(71) Applicant: BOE TECHNOLOGY GROUP CO., LTD., Beijing (CN)

(72) Inventor: Fengjuan LIU, Beijing (CN)

(73) Assignee: BOE TECHNOLOGY GROUP CO., LTD., Beijing (CN)

(21) Appl. No.: 15/559,098

(22) PCT Filed: Mar. 16, 2017
(86) PCT No.: PCT/CN2017/076951

§ 371 Date: Sep. 18, 2017

(30) Foreign Application Priority Data
May 26, 2016 (CN) 201610362366.2

(51) Int. Cl. H01L 29/786; H01L 29/66; H01L 27/12; H01L 21/467

(52) U.S. Cl. CPC H01L 29/7869; H01L 29/66969; H01L 21/467; H01L 27/124; H01L 27/1248; H01L 27/1225

(57) ABSTRACT

A thin film transistor, and a method for manufacturing the thin film transistor, a base substrate and a display device are provided. The method includes: forming a semiconductor layer on a base substrate, wherein the semiconductor layer includes a pattern of a first metal oxide and a pattern of a second metal oxide covering the pattern of the first metal oxide; and etching, through a mask, a portion of the pattern of the second metal oxide out of a region of the mask by using etchant, wherein the mask is located within a region of the pattern of the second metal oxide, and the etchant chemically reacts with a surface of a portion of the pattern of the first metal oxide out of the region of the mask, to form conductors serving as a source electrode and a drain electrode.

### CROSS-REFERENCE TO RELATED APPLICATION

The present application claims priority to Chinese patent application No. 201610362366.2 filed on May 26, 2016, the disclosure of which is incorporated herein in its entirety by reference.

### TECHNICAL FIELD

The present disclosure relates to the field of display device manufacturing, and more particularly to a thin film transistor (TFT) and a method for the same, a base substrate and a display device.

### BACKGROUND

In related art, as shown in FIG. 1, in a method for manufacturing a top-gate metal oxide TFT of a display device, generally, it deposits a layer of semiconductor pattern 2 on a base substrate 1, and then forming a gate electrode G on the semiconductor pattern, and subjecting, through the gate electrode G serving as a mask, a region of the semiconductor pattern 2 not covered by the gate electrode G to a conducting process through a conducting process such as a plasma treatment, to form a source electrode S and a drain electrode D. This method has advantage in that both a manufacturing process and a structure of the pattern layer of the TFT are relatively simple.

However, a conducting result acquired through such plasma treatment process is instable, so that there is a risk of increasing source-drain resistance at a later stage, which may adversely affect a reliability of a component. Moreover, it can be seen from FIG. 1 that, in the TFT manufactured through the method, the source electrode S, the drain electrode D and a semiconductor layer therebetween are of a single layer structure, which may increase an off-state current, lower a stability of the TFT, and thereby adversely affect a display quality of a display device.

### SUMMARY

An object of the present disclosure is to provide a solution capable of improving the off-state current and the stability of the TFT.

In order to achieve the above object, in one aspect, the present disclosure provides a method for manufacturing a TFT, including: forming a semiconductor layer on a base substrate, wherein the semiconductor layer includes a pattern of a first metal oxide and a pattern of a second metal oxide in sequence, and the pattern of the second metal oxide covers the pattern of the first metal oxide; and etching, through a mask, a portion of the pattern of the second metal oxide out of a region of the mask by using etchant, wherein the mask is located within a region of the pattern of the second metal oxide, and the etchant chemically reacts with a surface of a portion of the pattern of the first metal oxide out of the region of the mask, to form conductors serving as a source electrode and a drain electrode.

Optionally, the method according to the present disclosure further includes: forming a gate insulation layer and a gate electrode in sequence on the base substrate on which the semiconductor layer has been formed, wherein the gate insulation layer is located within a region of the gate electrode, and configured to insulate the gate electrode from the second metal oxide, and the gate electrode serves as the mask for etching the portion of the pattern of the second metal oxide.

Optionally, the forming the gate insulation layer and the gate electrode in sequence on the base substrate on which the semiconductor layer has been formed includes: depositing an insulation material layer and an electrically-conductive material layer in sequence on base substrate on which the semiconductor layer has been formed; subjecting the electrically-conductive material layer to a patterning process to obtain the gate electrode; and etching, through the gate electrode serving as the mask, a portion of the insulation material layer out of the region of the gate electrode, to obtain the gate insulation layer.

Optionally, the first metal oxide is made of stanniferous metal oxide (In₂O₃)ₐ(SnO₂)_{b}(MO)_{c}(ZnO)_{d}, wherein 0≤a≤1, 0≤b≤1, 0≤c≤1, 0≤d≤1, a+b+c+d=1, and M is any one of Ga, Al and Mg; the second metal oxide is made of (In₂O₃)ₑ(NO)_{f}(ZnO)_{g}, wherein 0≤e≤1, 0≤f≤1, 0≤g≤1, e+f+g=1, and N is any one of Ga, Al and Mg.

Optionally, the etchant is a mixed solution of acetic acid, phosphoric acid and nitric acid.

Optionally, the etchant is acidic.

Optionally, the forming the semiconductor layer on the base substrate includes: depositing a layer of the first metal oxide and a layer of the second metal oxide in sequence on the base substrate; and subjecting the layer of the first metal oxide and the layer of the second metal oxide to a single patterning process, to obtain the pattern of the first metal oxide formed by the layer of the first metal oxide and the pattern of the second metal oxide formed by the layer of the second metal oxide.

Optionally, the forming the semiconductor layer on the base substrate includes: forming the pattern of the first metal oxide on the base substrate through a single patterning process; and depositing the pattern of the second metal oxide covering the pattern of the first metal oxide.

In another aspect, the present disclosure further provides a TFT, including a semiconductor layer, a source electrode and a drain electrode, wherein the semiconductor layer includes a pattern of a first metal oxide and a pattern of a second metal oxide; the pattern of the second metal oxide is located within a region of the pattern of the first metal oxide, and conductors serving as the source electrode and the drain electrode are formed on a surface of a portion of the region of the first metal oxide not covered by the pattern of the second metal oxide.

Optionally, the TFT according to the present disclosure further includes a gate electrode and a gate insulation layer, wherein the gate insulation layer is located within a region of the gate electrode, and configured to insulate the gate electrode from the second metal oxide, and the pattern of the second metal oxide is located within the region of the gate electrode.

In addition, the present disclosure further provides an array substrate including the above TFT.

Optionally, the above array substrate further includes a buffer layer arranged between the semiconductor layer and the base substrate.

Optionally, the above array substrate further includes: a planarization layer covering the semiconductor layer; and a data line and a pixel electrode formed on the planarization layer, wherein the planarization layer includes a first via hole and a second via hole, the first via hole is arranged opposite to the source electrode, the second via hole is arranged opposite to the drain electrode, the data line is connected to the source electrode through the first via hole, and the pixel electrode is connected to the drain electrode through the second via hole.

In addition, the present disclosure further provides a display device including the above array substrate.

Advantageous effects of the present disclosure are as follows.

In the technical solution according to the present disclosure, two different patterns of metal oxides are deposited in sequence to serve as the semiconductor layer. An acidic etching solution is used to etch a pattern of the metal oxide in an upper layer, and chemically reacts with an exposed pattern of the metal oxide in a lower layer to form conductors serving as the source electrode and the drain electrode. As compared with the solution of the top-gate metal oxide TFT in the prior art where the source electrode and the drain electrode are formed through the plasma treatment process, resistances of conductors generated through the chemical method according to the present disclosure are more stable, and the source electrode and the drain electrode and a channel layer of the TFT are located in different layers, which may effectively reduce the off-state current of the TFT.

### BRIEF DESCRIPTION OF THE DRAWINGS

In order to make the technical solutions in embodiments of the present disclosure more apparent, drawings need to be used in the embodiments will be briefly described hereinafter. Obviously, drawings in the following descriptions are merely some of the embodiments of the present disclosure, and based on these drawings, a person skilled in the art may obtain other drawings without any creative labors. The described drawings are not necessarily drawn to scales respect to actual sizes and are merely for illustration purposes only.

FIG. 1 is a schematic view showing a formation of a source electrode and a drain electrode on a semiconductor layer through a plasma treatment process in the related art.

FIG. 2A-2C are schematic views showing a method for manufacturing a TFT according to the present disclosure;

FIG. 3 is a schematic view showing a formation of a top-gate TFT through the method according to the present disclosure;

FIG. 4A-4E are detailed schematic views showing a formation of the top-gate TFT through the method according to the present disclosure;

FIG. 5 is a schematic view showing a structure of an array substrate according to the present disclosure.

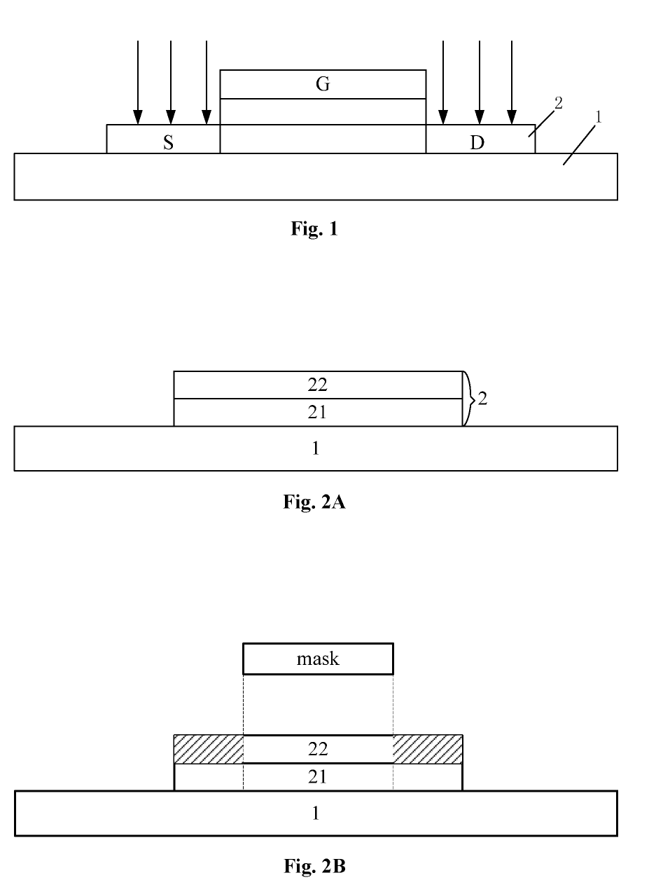

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “a” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

The present disclosure provides a solution, so as to solve a problem in the related art where the off-state current of the top-gate oxide TFT is large and the reliability of the component is poor.

In one aspect, the present disclosure provides in some embodiments a method for manufacturing a TFT, including the following steps.

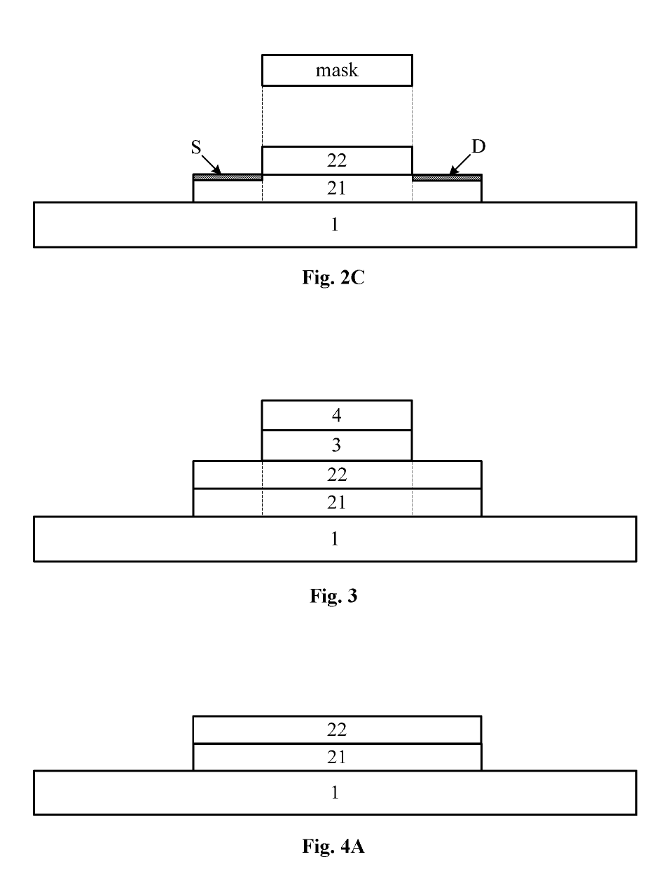

Step 1: referring to FIG. 2A, forming a semiconductor layer 2 on a base substrate 1, wherein the semiconductor layer 2 includes a pattern of a first metal oxide 21 and a pattern of a second metal oxide 22 in sequence, and the pattern of the second metal oxide 22 covers the pattern of the first metal oxide 21.

Step 2: referring to FIG. 2B, etching, through a mask, a portion of the pattern of the second metal oxide 22 out of a region of the mask by using acidic etchant, wherein, referring to FIG. 2C, the acidic etchant chemically reacts with a surface of a portion of the pattern of the first metal oxide 21 out of the region of the mask, to form conductors serving as a source electrode S and a drain electrode D.

According to the embodiment, for example, the first metal oxide is made of stanniferous metal oxide (In₂O₃)ₐ(SnO₂)_{b}(MO)_{c}(ZnO)_{d}, wherein 0≤a≤1, 0≤b≤1, 0≤c≤1, 0≤d≤1, a+b+c+d=1, and M is any one of Ga, Al and Mg; and the second metal oxide is made of (In₂O₃)ₑ(NO)_{f}(ZnO)_{g}, wherein 0≤e≤1, 0≤f≤1, 0≤g≤1, e+f+g=1, and N is any one of Ga, Al and Mg.

In this embodiment, corresponding to the above material of the semiconductor layer, the acidic etchant may be a mixed solution of acetic acid, phosphoric acid and nitric acid, and is capable of effectively dissolving the above second metal oxide (In₂O₃)ₑ(NO)_{f}(ZnO)_{g}, and chemically reacts with the first metal oxide (In₂O₃)ₐ(SnO₂)_{b}(MO)_{c}(ZnO)_{d} to form a tin-rich layer of a high electrical conductivity on the surface of the first metal oxide.

Obviously, it can be seen from FIG. 2C that, according to the embodiment, the portion of the pattern of second metal oxide 22 not being etched and serving as a part of the pattern of the semiconductor should be higher than the source electrode S and the drain electrode D, so as to effectively reduce the off-state currents of the source electrode S and the drain electrode D, and thus effectively improving a switching activity of the TFT.

Furthermore, in the embodiment, referring to FIG. 3, before the step 2, the method further includes: forming a gate insulation layer 3 and a gate electrode 4 in sequence on the base substrate on which the semiconductor layers 21, 22 have been formed, wherein the gate insulation layer 3 is located within a region of the gate electrode 4, and configured to insulate the gate electrode 4 from the semiconductor layers 21, 22.

According to the embodiment, in the above step 2, the pattern of the gate electrode 4 further serves as a mask to etch the pattern of the second metal oxide 22. Since no new dedicated mask is introduced in this etching step, the manufacturing cost is effectively reduced, and thus has a high practical value.

In the following, the method for manufacturing the TFT will be described in details in conjunction with a practical implementation.

In the practical implementation, the method for manufacturing the TFT includes the following steps.

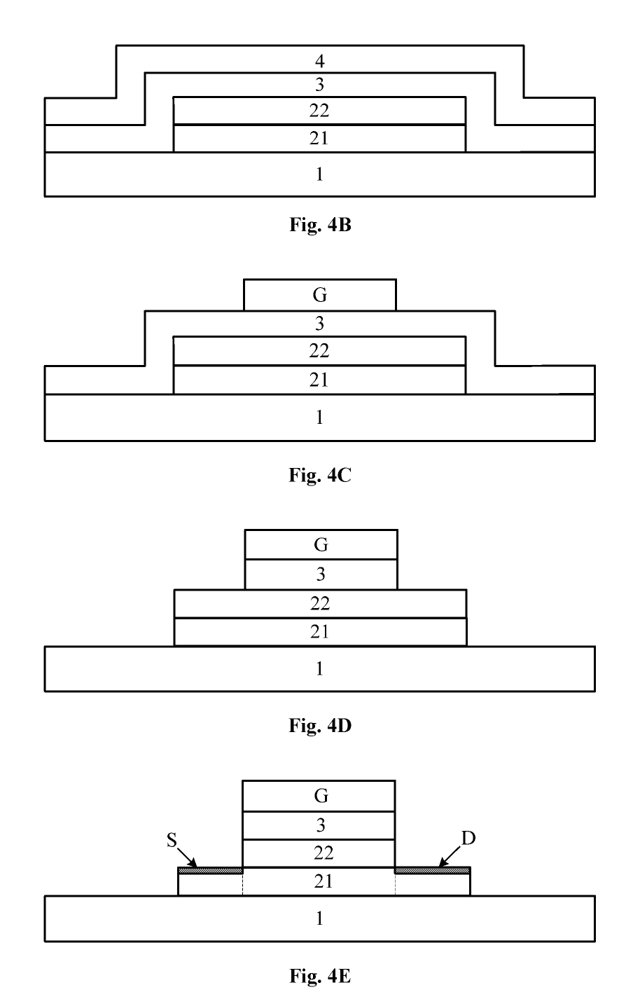

Step 41: referring to FIG. 4A, depositing a layer of the first metal oxide and a layer of the second metal oxide in sequence on the base substrate, and subjecting the layer of the first metal oxide and the layer of the second metal oxide to a single patterning process, to obtain the pattern of the first metal oxide 21 formed by the layer of the first metal oxide and the pattern of the second metal oxide 22 formed by the layer of the second metal oxide (obviously, as an alternate to the step 41, firstly the pattern of the first metal oxide 21 may be formed through a single patterning process, and then the pattern of the second metal oxide 22 capable of covering the pattern of the first metal oxide 21 may be directly deposited).

Step 42: referring to FIG. 4B, depositing an insulation material layer 3 and an electrically-conductive material layer 4 in sequence.

Step 43: referring to FIG. 4C, subjecting the electrically-conductive material layer 4 to a patterning process to form a gate electrode G.

Step 44: referring to FIG. 4D, etching, through the gate electrode G serving as the mask, a portion of the insulation material layer 3 out of the region of the gate electrode G, to obtain the gate insulation layer 3 located within the region of the gate electrode G.

Step 45: referring to FIG. 4E, etching, through the gate electrode G serving as the mask, a portion of the pattern of the second metal oxide 22 out of the region of the gate electrode G by using acidic etchant. During the etching process, an etched portion of the pattern of second metal oxide 22 may expose the pattern of the first metal oxide 21, and the acidic etchant chemically reacts with the exposed pattern of the first metal oxide 21 to form the source electrode S and the drain electrode D on the surface of the first metal oxide 21.

Obviously, it can be seen from the above steps 41-45 that, in this embodiment, the acidic etchant is used to etch the pattern of the second metal oxide, and portions of the region of the pattern of the first metal oxide is subjected to the conducting process to form the source electrode and the drain electrode. In such method, a manufacturing process is simple, and the cost is reduced because the gate electrode serves as the mask.

In addition, it should be noted that, as an alternate to the above practical implementation, according to the embodiment, after subjecting the gate electrode to the patterning process, photoresist used for etching the gate electrode may be reserved, such that upon etching the pattern of the second metal oxide and the gate insulation layer through the gate electrode serving as the mask at a later stage, the mask may be the gate electrode and an entire structure of the reserved photoresist.

In addition, the present disclosure further provides in another embodiment a TFT corresponding to the above method. As shown in FIG. 4E, the TFT includes: a semiconductor layer formed by the pattern of the first metal oxide 21 and the pattern of the second metal oxide 22, a source electrode S and a drain electrode D. The pattern of the second metal oxide 22 covers partial regions of the pattern of the first metal oxide 21, and conductors serving as the above source electrode S and the above drain electrode D are formed on a surface of a portion of the region of the first metal oxide 21 not covered by the pattern of the second metal oxide 22.

Specifically, in this embodiment, the TFT further includes a gate electrode G and a gate insulation layer 3, wherein the gate insulation layer 3 is located within a region of the gate electrode G, and configured to insulate the gate electrode G from the semiconductor layer, and the pattern of the second metal oxide 22 is located within the region of the gate electrode G.

According to the embodiment, the TFT is obtained through the above method for manufacturing the TFT, therefore same technical effects may be realized.

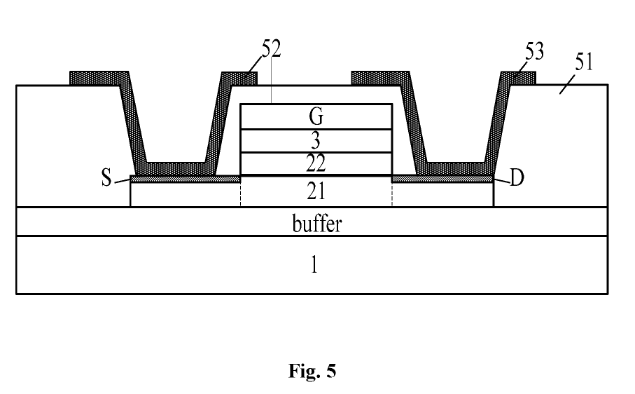

In addition, the present disclosure further provides in another embodiment an array substrate including the above TFT. In a practical implementation, it assumes that, according to the embodiment, the array substrate adopts the structure of the TFT formed on the base substrate 1 in FIG. 4. Further referring to FIG. 5, according to the embodiment, a buffer layer “buffer” is further arranged between the base substrate 1 and the TFT, and the buffer layer “buffer” is capable of preventing a thermal stress of the base substrate 1 from damaging the TFT.

Furthermore, according to the embodiment, the array substrate further includes: a planarization layer 51 covering the semiconductor layer; and a data line 52 and a pixel electrode 53 formed on the planarization layer 51.

The planarization layer 5 includes a first via hole and a second via hole, the first via hole is arranged opposite to the source electrode in the TFT, the second via hole is arranged opposite to the drain electrode in the TFT, the data line 52 is connected to the source electrode S through the first via hole, and the pixel electrode 53 is connected to the drain electrode D through the second via hole.

In addition, the present disclosure further provides a display panel including the above array substrate, which includes the TFT according to the present disclosure, so as to provide a more stable display image may be provided, and improve user experience.

The above are merely the optional embodiments of the present disclosure, and it should be noted that, a person skilled in the art may make improvements and modifications without departing from the principle of the present disclosure, and these improvements and modifications shall also fall within the scope of the present disclosure.

1. A method for manufacturing a thin film transistor (TFT), comprising:
forming a semiconductor layer on a base substrate, wherein the semiconductor layer comprises a pattern of a first metal oxide and a pattern of a second metal oxide in sequence, and the pattern of the second metal oxide covers the pattern of the first metal oxide; and
etching, through a mask, a portion of the pattern of the second metal oxide out of a region of the mask by using etchant, wherein the mask is located within a region of the pattern of the second metal oxide, and the etchant chemically reacts with a surface of a portion of the pattern of the first metal oxide out of the region of the mask, to form conductors serving as a source electrode and a drain electrode.

2. The method according to claim 1, further comprising:
forming a gate insulation layer and a gate electrode in sequence on the base substrate on which the semiconductor layer has been formed,
wherein the gate insulation layer is located within a region of the gate electrode, and
configured to insulate the gate electrode from the second metal oxide, and the gate electrode serves as the mask for etching the portion of the pattern of the second metal oxide.

3. The method according to claim 2, wherein the forming the gate insulation layer and the gate electrode in sequence on the base substrate on which the semiconductor layer has been formed comprises:
depositing an insulation material layer and an electrically-conductive material layer in sequence on the base substrate on which the semiconductor layer has been formed;
subjecting the electrically-conductive material layer to a patterning process to obtain the gate electrode; and
etching, through the gate electrode serving as the mask, a portion of the insulation material layer out of the region of the gate electrode, to obtain the gate insulation layer.

4. The method according to claim 1, wherein
the first metal oxide is made of stanniferous metal oxide (In₂O₃)ₐ(SnO₂)_{b}(MO)_{c}(ZnO)_{d}, wherein 0≤a≤1, 0≤b≤1, 0≤c≤1, 0≤d≤1, a+b+c+d=1, and M is any one of Ga, Al and Mg; and
the second metal oxide is made of (In₂O₃)ₑ(NO)_{f}(ZnO)_{g}, wherein 0≤e≤1, 0≤f≤1, 0≤g≤1, e+f+g=1, and N is any one of Ga, Al and Mg.

5. The method according to claim 4, wherein
the etchant is a mixed solution of acetic acid, phosphoric acid and nitric acid.

6. The method according to claim 1, wherein the etchant is acidic.

7. The method according to claim 1, wherein the forming the semiconductor layer on the base substrate comprises:
depositing a layer of the first metal oxide and a layer of the second metal oxide in sequence on the base substrate; and
subjecting the layer of the first metal oxide and the layer of the second metal oxide to a single patterning process, to obtain the pattern of the first metal oxide formed by the layer of the first metal oxide and the pattern of the second metal oxide formed by the layer of the second metal oxide.

8. The method according to claim 1, wherein the forming the semiconductor layer on the base substrate comprises:
forming the pattern of the first metal oxide on the base substrate through a single patterning process; and
depositing the pattern of the second metal oxide covering the pattern of the first metal oxide.

9. A Thin Film Transistor (TFT), comprising a semiconductor layer, a source electrode and a drain electrode,
wherein the semiconductor layer comprises a pattern of a first metal oxide and a pattern of a second metal oxide; the pattern of the second metal oxide is located within a region of the pattern of the first metal oxide, and conductors serving as the source electrode and the drain electrode are formed on a surface of a portion of the region of the first metal oxide not covered by the pattern of the second metal oxide.

10. The TFT according to claim 9, further comprising a gate electrode and a gate insulation layer,
wherein the gate insulation layer is located within a region of the gate electrode, and configured to insulate the gate electrode from the second metal oxide, and the pattern of the second metal oxide is located within the region of the gate electrode.

11. An array substrate comprising a base substrate and the TFT according to claim 9, wherein the TFT is formed on the base substrate.

12. The array substrate according to claim 11, further comprising a buffer layer arranged between the semiconductor layer and the base substrate.

13. The array substrate according to claim 11, further comprising:
a planarization layer covering the semiconductor layer; and
a data line and a pixel electrode formed on the planarization layer,
wherein the planarization layer comprises a first via hole and a second via hole, the first via hole is arranged opposite to the source electrode, the second via hole is arranged opposite to the drain electrode, the data line is connected to the source electrode through the first via hole, and the pixel electrode is connected to the drain electrode through the second via hole.

14. A display device comprising the array substrate according to claim 11.

15. The display device according to claim 14, wherein the array substrate further comprises a buffer layer arranged between the semiconductor layer and the base substrate.

16. The display device according to claim 14, wherein the array substrate further comprises:
a planarization layer covering the semiconductor layer; and
a data line and a pixel electrode formed on the planarization layer,
wherein the planarization layer comprises a first via hole and a second via hole, the first via hole is arranged opposite to the source electrode, the second via hole is arranged opposite to the drain electrode, the data line is connected to the source electrode through the first via hole, and the pixel electrode is connected to the drain electrode through the second via hole.

17. An array substrate comprising a base substrate and the TFT according to claim 10, wherein the TFT is formed on the base substrate.

18. The array substrate according to claim 17, further comprising a buffer layer arranged between the semiconductor layer and the base substrate.

19. The array substrate according to claim 17, further comprising:
a planarization layer covering the semiconductor layer; and
a data line and a pixel electrode formed on the planarization layer,
wherein the planarization layer comprises a first via hole and a second via hole, the first via hole is arranged opposite to the source electrode, the second via hole is arranged opposite to the drain electrode, the data line is connected to the source electrode through the first via hole, and the pixel electrode is connected to the drain electrode through the second via hole.

20. A display device comprising the array substrate according to claim 17.
